(19) United States
(12) Patent Application Publication
(10) Pub. No.: US 2024/0413189 A1
(43) Pub. Date: Dec. 12, 2024

(54) Optical Sensor Integration

(71) Applicant: Artilux, Inc., Menlo Park, CA (US)

(72) Inventors: Yun-Chung Na, San Jose, CA (US); Yu-Hsuan Liu, HSINCHU COUNTY (TW); Yi-Chuan Teng, HSINCHU COUNTY (TW); Tsung-Ting Wu, HSINCHU COUNTY (TW)

(21) Appl. No.: 18/732,147

(22) Filed: Jun. 3, 2024

Related U.S. Application Data
(60) Provisional application No. 63/472,352, filed on Jun. 12, 2023.

(51) Int. Cl. H01L 27/146

(52) U.S. Cl. CPC H01L 27/14687; H01L 27/14685

(57) ABSTRACT

A method for manufacturing one or more optical sensor packages includes forming a bonded wafer by bonding (i) a device wafer comprising a plurality of optical sensing pixels and (ii) a circuit wafer comprising application-specific-integrated-circuit configured to operate the optical sensing pixels, where the bonded wafer includes a device-wafer surface and a circuit-wafer surface. The method also includes forming a plurality of microlens arrays over the device-wafer surface, where each microlens of the microlens arrays corresponds to a particular optical sensing pixel. The method also includes forming a plurality of module-lens structures over the plurality of microlens arrays, where each module-lens structure corresponds to a particular microlens array of the plurality of microlens arrays. The method also includes forming electrical contacts over the circuit-wafer surface to establish electrical connections to the plurality of optical sensing pixels and the application-specific-integrated-circuit.

### RELATED APPLICATIONS

The present application claims filing benefit of U.S. Provisional Patent Application Ser. No. 63/472,352 having a filing date of Jun. 12, 2023, which is incorporated herein by reference in its entirety.

### FIELD

The present disclosure relates generally to module level packaging technology for use with optical sensors (e.g., photodetectors) and related applications.

### BACKGROUND

Optical sensors are being used in many applications, such as smartphones, wearables, robotics, and autonomous vehicles, etc. for object recognition, image enhancement, material recognition, and other relevant applications. A photodetector may be used to detect optical signals and convert the optical signals to electrical signals that may be further processed by other circuitry. Photodetectors may be especially useful in consumer electronics products, proximity sensing, image sensors, data communications, direct or indirect time-of-flight (TOF) ranging or imaging sensors, and many other suitable applications.

### SUMMARY

Aspects and advantages of embodiments of the present disclosure will be set forth in part in the following description, or may be learned from the description, or may be learned through practice of the embodiments.

One example aspect of the present disclosure is directed to a method for manufacturing one or more optical sensor packages. The method includes forming a bonded wafer by bonding (i) a device wafer comprising a plurality of optical sensing pixels and (ii) a circuit wafer comprising application-specific-integrated-circuit configured to operate the optical sensing pixels, where the bonded wafer includes a device-wafer surface and a circuit-wafer surface; forming a plurality of microlens arrays over the device-wafer surface, where each microlens of the microlens arrays corresponds to a particular optical sensing pixel; forming a plurality of module-lens structures over the plurality of microlens arrays, where each module-lens structure corresponds to a particular microlens array of the plurality of microlens arrays; and forming electrical contacts to establish electrical connections to the plurality of optical sensing pixels and the application-specific-integrated-circuit.

In some implementations, forming the electrical contacts further includes forming the electrical contacts over the circuit-wafer surface. In some implementations, forming the electrical contacts further includes forming the electrical contacts over the device-wafer surface. In some implementations, forming the electrical contacts further includes forming through-silicon-vias (TSV) in the circuit wafer or the device wafer, and forming electrical bond pads over the through-silicon-vias. In some implementations, forming the electrical contacts further includes polishing the circuit wafer to a predetermined thickness prior to forming the electrical contacts.

In some implementations, the plurality of microlens arrays include a first spacer structure and a microlens surface, where the first spacer structure is formed between the device-wafer surface and the microlens surface. In some implementations, forming the plurality of microlens arrays over the device-wafer surface further includes polishing the device-wafer to a predetermined thickness before forming the plurality of microlens arrays. In some implementations, the plurality of microlens arrays include polymer materials or one or more layers of metalens.

In some implementations, the plurality of module-lens structures include a module-lens surface and a second spacer structure formed between the device-wafer surface and the module-lens surface, where a thickness of the second spacer structure corresponds to a focal length associated with the module-lens surface. In some implementations, forming the plurality of module-lens structures further includes forming a band pass filter (i) over the module-lens surface or (ii) between the second spacer structure and the module-lens surface. In some implementations, the thickness of the second spacer structure ranges from 100 μm to 3000 μm. In some implementations, each of the plurality of module-lens structures includes a curved lens or a metalens. In some implementations, the second spacer structure includes a polymer material, a dielectric material, or silicon.

In some implementations, forming the plurality of module-lens structures over the plurality of microlens arrays further includes arranging a module lens structure of the plurality of module-lens structures in a housing, and bonding the housing to the bonded wafer. In some implementations, forming the plurality of module-lens structures over the plurality of microlens arrays further includes bonding a module lens structure of the plurality of module-lens structures to the bonded wafer using one or more layers of spacer materials including one or more of polymer or oxide.

In some implementations, the method may further include dicing the bonded wafer after forming the electrical contacts. In some implementations, the method may further include dicing the bonded wafer prior to forming the plurality of module-lens structures. In some implementations, the method may further include forming wire bonds between the electrical contacts and a package substrate, where the package substrate includes a printed circuit board or a silicon substrate. In some implementations, the device wafer and the circuit wafer include silicon, and wherein the plurality of optical sensing pixels include germanium.

Another example aspect of the present disclosure is directed to an optical sensor package that includes a bonded substrate having a device-wafer surface and a circuit-wafer surface. The bonded substrate includes a device substrate having a plurality of optical sensing pixels, a circuit substrate bonded with the device substrate, where the circuit substrate includes circuitry configured to operate the optical sensing pixels. The optical sensor package further includes a microlens array formed over the device-wafer surface, where each microlens of the microlens arrays corresponds to a particular optical sensing pixel. The optical sensor package further includes a module-lens structure formed over the microlens array. The optical sensor package further includes electrical contacts formed over the circuit-wafer surface to establish electrical connections to the plurality of optical sensing pixels and the application-specific-integrated-circuit.

In some implementations, the circuit wafer has been polished to a predetermined thickness. In some implementations, the device wafer and the circuit wafer may be silicon wafers, where the plurality of optical sensing pixels include germanium material. In some implementations, the bonded wafer further includes one or more dielectric layers and one or more metal layers that provide electrical connections between the device wafer and the circuit wafer.

In some implementations, the microlens array includes a first spacer structure and a microlens surface, where the first spacer structure is formed between the device-wafer surface and the microlens surface. In some implementations, the microlens array are formed using polymer materials.

In some implementations, the module-lens structure includes a module-lens surface and a second spacer structure formed between the device-wafer surface and the module-lens surface. In some implementations, each of the module-lens structure includes a curved lens or a metalens. In some implementations, a thickness of the second spacer structure corresponds to a focal length associated with the module-lens surface. The thickness of the second spacer structure may range from 100 μm to 3000 μm. The second spacer structure may be formed using a polymer material, silicon, or a dielectric material. In some implementations, the module-lens structure further includes a band pass filter formed over the module-lens surface or between the second spacer structure and the module-lens surface.

In some implementations, the electrical contacts include through-silicon-vias (TSV) formed in the circuit wafer, and electrical bond pads formed over the through-silicon-vias. In some implementations, one or more properties associated with the microlens array or the module-lens structure is tunable by a voltage bias. The one or more properties may include a pass-band wavelength, a transmission percentage, or a focusing length associated with the microlens array or the module-lens structure.

Another example aspect of the present disclosure is directed to an optical sensor package that includes a bonded substrate having a device-wafer surface and a circuit-wafer surface. The bonded substrate includes a device substrate having a plurality of optical sensing pixels, a circuit substrate bonded with the device substrate, where the circuit substrate includes circuitry configured to operate the optical sensing pixels. The optical sensor package further includes a microlens array formed over the device-wafer surface, where each microlens of the microlens arrays corresponds to a particular optical sensing pixel. The optical sensor package further includes a module-lens structure formed over the microlens array. The optical sensor package further includes electrical contacts formed over the device-wafer surface to establish electrical connections to the plurality of optical sensing pixels and the application-specific-integrated-circuit.

Another example aspect of the present disclosure is directed to a method for manufacturing an optical sensor package that integrates a transmitter chip and a receiver chip. The process includes bonding a transmitter chip and a receiver chip to a module lens structure having a spacer structure, a module-lens surface, and a band-pass filter, where the module lens structure has a larger area than the transmitter chip and the receiver chip.

In some implementations, the method may further include forming a trench in the module lens structure. In some implementations, the method may further include forming a planarization layer, forming electrical contacts to establish electrical connections to the transmitter chip and the receiver chip, and bonding planarization layer to a package substrate, where the package substrate may be a printed circuit board or a silicon substrate.

Other example aspects of the present disclosure are directed to systems, methods, apparatuses, sensors, computing devices, tangible non-transitory computer-readable media, and memory devices related to the described technology.

These and other features, aspects and advantages of various embodiments will become better understood with reference to the following description and appended claims. The accompanying drawings, which are incorporated in and constitute a part of this specification, illustrate embodiments of the present disclosure, and together with the description, serve to explain the related principles.

### BRIEF DESCRIPTION OF THE DRAWINGS

The foregoing aspects and many of the attendant advantages of this application will become more readily appreciated by reference to the following detailed description, when taken in conjunction with the accompanying drawings, where:

FIG. 1A illustrates an example process for manufacturing an optical sensor package.

FIG. 1B illustrates an example optical sensor package.

FIG. 2A illustrates an example process for manufacturing an optical sensor package.

FIG. 2B illustrates an example optical sensor package.

FIGS. 3A-3B illustrate an example process for manufacturing an optical sensor package.

FIG. 3C illustrates an example optical sensor package.

FIG. 4 illustrates an example process for manufacturing an optical sensor package.

FIGS. 5 and 6 illustrate examples of an optical sensor package.

### DETAILED DESCRIPTION

An optical sensor, or a photodetector, may be used to detect optical signals and convert the optical signals to electrical signals that may be further processed by another circuitry. Photodetectors may be used in systems such as smartphones, wearable electronics, robotics, and autonomous vehicles, etc. for proximity detection, 2D/3D imaging, object recognition, image enhancement, material recognition, color fusion, health monitoring, eye-tracking, gesture tracking, and other relevant applications. The photodetectors can be operable for different wavelength ranges, including visible (e.g., wavelength range 380 nm to 780 nm, or a similar wavelength range as defined by a particular application) and non-visible light. The non-visible light includes near-infrared (NIR, e.g., wavelength range from 780 nm to 1400 nm, or a similar wavelength range as defined by a particular application) and short-wavelength infrared (SWIR, e.g., wavelength range from 1400 nm to 3000 nm, or a similar wavelength range as defined by a particular application) light.

Conventional module-level packaging for array sensors includes a glass lens with a large z-height. The present disclosure describes embodiments of a wafer-level module lens optics package in order to reduce the height of a module lens in a module-level package. As an example, a large glass lens can be replaced by a silicon module-level lens (e.g., meta lens). With wafer level module lens having a high refractive index contrast (e.g., n_glass>1.5, n_Si=3.5 at 1310 nm) compared to traditional glass base module lens, technical advantages such as higher IR transmission, tunable numerical aperture, small package size, cost efficiency, and CMOS process compatibility can be achieved.

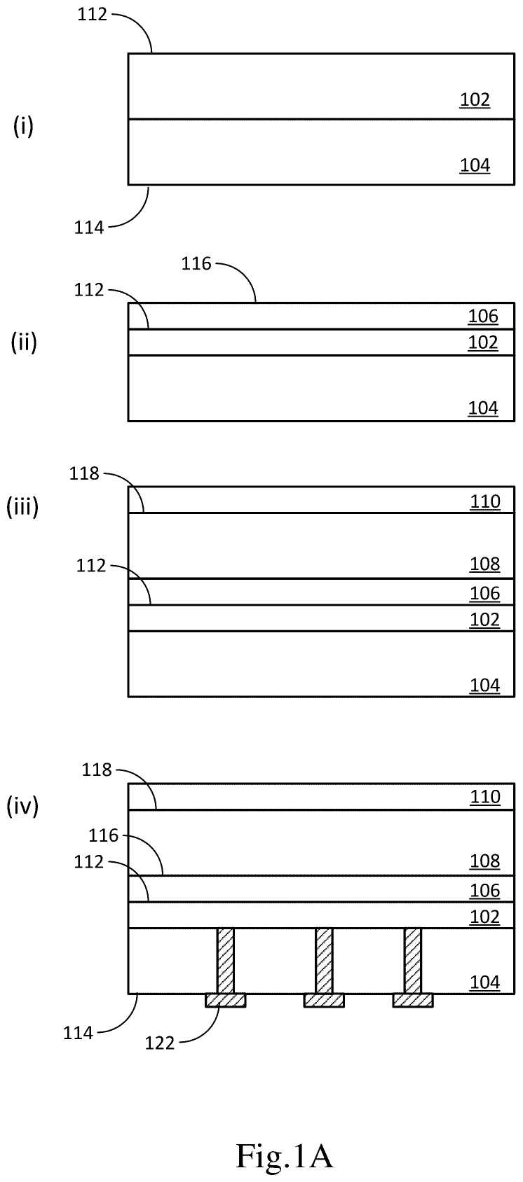

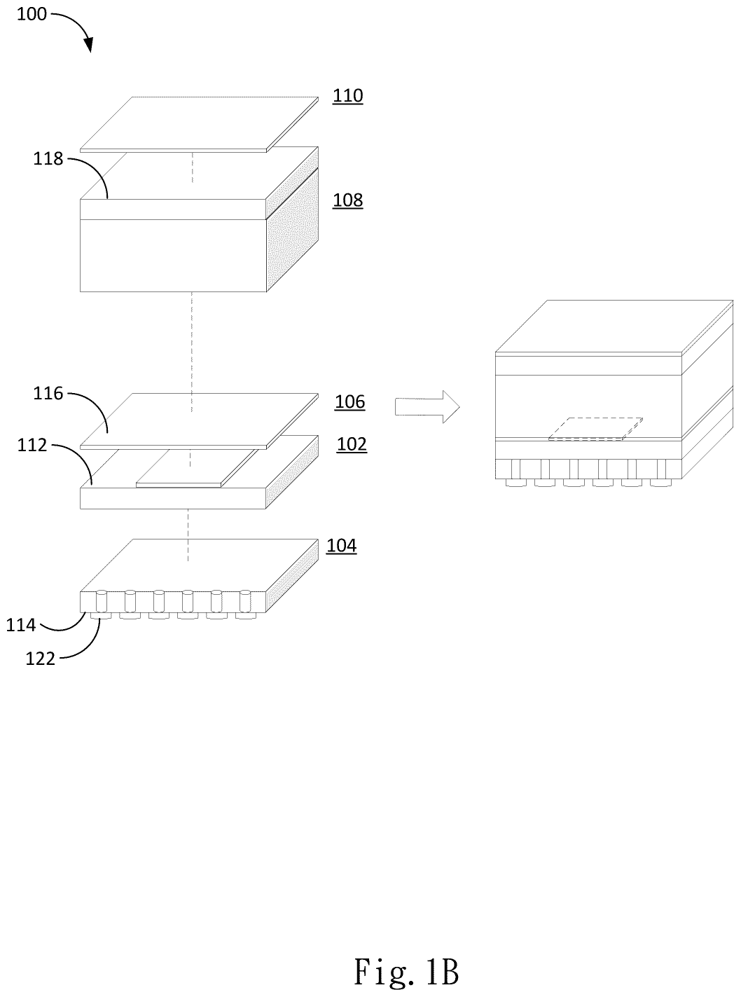

FIG. 1A illustrates an example process for manufacturing an optical sensor package. The process may be performed by, e.g., equipment in a semiconductor-processing facility (e.g., cleanroom) and/or integrated circuit packaging/assembly facility, etc. Referring to step (i) in FIG. 1A, the process includes forming a bonded wafer by bonding a device wafer 102 having a plurality of optical sensing pixels and a circuit wafer 104 having circuitry (e.g., application-specific-integrated-circuit) configured to operate the optical sensing pixels, where the bonded wafer includes a device-wafer surface 112 and a circuit-wafer surface 114. The device wafer 102 and the circuit wafer 104 may be silicon wafers, and the plurality of optical sensing pixels may include germanium absorption regions. In some implementations, forming the bonded wafer includes hybrid-bonding the device wafer 102 and the circuit wafer 104 with one or more dielectric layers and one or more metal layers (not shown) that provide electrical connections between the device wafer 102 and the circuit wafer 104.

Referring to step (ii) in FIG. 1A, the process further includes forming a plurality of microlens arrays 106 over the device-wafer surface 112, where each microlens of the microlens arrays 106 corresponds to a particular optical sensing pixel. The plurality of microlens arrays can include polymer materials. In some implementations, the plurality of microlens arrays 106 include a first spacer structure and a microlens surface 116, where the first spacer structure is formed between the device-wafer surface 112 and the microlens surface 116. In some implementations, forming the plurality of microlens arrays 106 over the device-wafer surface 112 may include polishing the device wafer 102 to a predetermined thickness before forming the plurality of microlens arrays 106.

Referring to step (iii) in FIG. 1A, the process further includes forming a plurality of module-lens structures 108 over the plurality of microlens arrays 106, where each module-lens structure 108 corresponds to a particular microlens array of the plurality of microlens arrays 106. In some implementations, the plurality of module-lens structures 108 include a module-lens surface 118 and a second spacer structure formed between the device-wafer surface 112 and the module-lens surface 118. In some implementations, each of the plurality of module-lens structures 108 includes a curved lens or a metalens. In some implementations, the second spacer structure includes a polymer material, a dielectric material, or silicon. In some implementations, a thickness of the second spacer structure corresponds to a focal length associated with the module-lens surface 118. For example, the thickness of the second spacer structure may range from 100 μm to 3000 μm. In some implementations, a module-lens structure 108 may include one or more additional spacer structures arranged under and/or over the module-lens surface 118. In some implementations, a module-lens structure 108 may include one or more additional module-lens surfaces separated by one or more additional spacer structures in order to further manipulate optical signals.

In some implementations, forming the plurality of module-lens structures 108 further includes forming a band pass filter 110 over the module-lens surface 118 or between the second spacer structure and the module-lens surface 118.

Referring to step (iv) in FIG. 1A, the process further includes forming electrical contacts 122 over the circuit-wafer surface 114 to establish electrical connections to the plurality of optical sensing pixels and the application-specific-integrated-circuit. In some implementations, forming the electrical contacts 122 over the circuit-wafer surface 114 includes forming through-silicon-vias (TSV) on the circuit wafer 104, and forming electrical bond pads over the through-silicon-vias. In some implementations, forming the electrical contacts 122 over the circuit-wafer surface 114 further includes polishing the circuit wafer 104 to a predetermined thickness prior to forming the TSV.

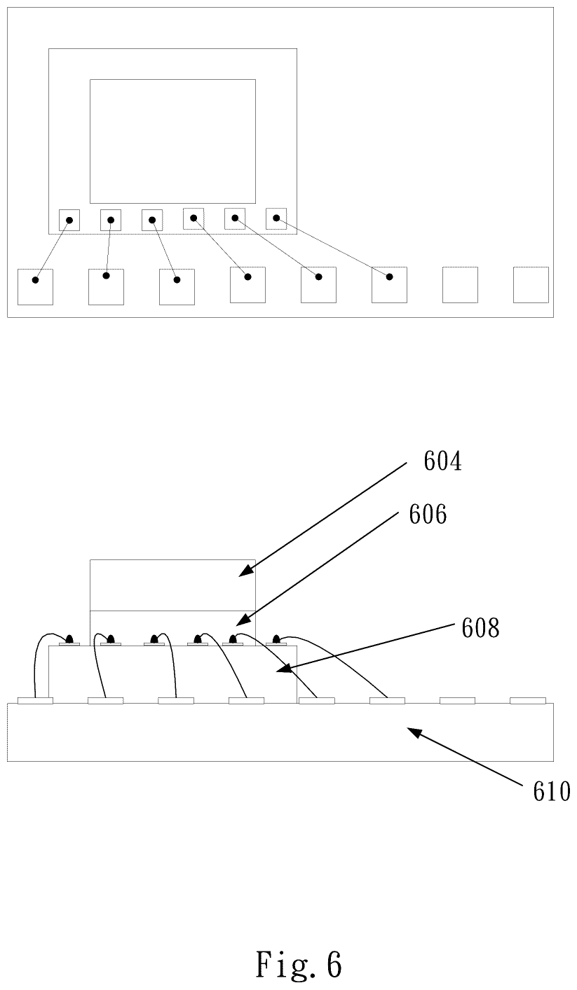

In some implementations, the process further includes thinning the circuit wafer 104 during the process (e.g., prior to forming the plurality of module-lens structures 108 over the plurality of microlens arrays 106, or prior to forming the electrical contacts 122, etc.). In some implementations, the process further includes dicing the bonded wafer after forming the electrical contacts 122. In some implementations, the process further includes forming wire bonds between the electrical contacts 122 and a package substrate, where the package substrate may be a printed circuit board or a silicon substrate. Referring to FIG. 6 as an example, the bonded chip 608 is bonded to the PCB 610 via wire bonds.

FIG. 1B illustrates an optical sensor package 100 manufactured by the process as described in reference to FIG. 1A. The optical sensor package 100 includes a bonded substrate having a device-wafer surface 112 and a circuit-wafer surface 114. The bonded substrate includes a device wafer 102 having a plurality of optical sensing pixels and a circuit wafer 104 bonded with the device wafer 102, where the circuit wafer 104 includes circuitry (e.g., application-specific-integrated-circuit) configured to operate the optical sensing pixels. In some implementations, the circuit wafer 104 has been polished to a predetermined thickness. In some implementations, the device wafer 102 and the circuit wafer 104 may be silicon wafers, where the plurality of optical sensing pixels include germanium material. In some implementations, the bonded wafer further includes one or more dielectric layers and one or more metal layers that provide electrical connections between the device wafer 102 and the circuit wafer 104.

The optical sensor package 100 further includes a microlens array 106 formed over the device-wafer surface 112, where each microlens of the microlens arrays 106 corresponds to a particular optical sensing pixel. In some implementations, the microlens array 106 includes a first spacer structure and a microlens surface 116, where the first spacer structure is formed between the device-wafer surface 112 and the microlens surface 116. In some implementations, the microlens array 106 is formed using polymer materials.

The optical sensor package 100 further includes a module-lens structure 108 formed over the microlens array 106. In some implementations, the module-lens structure 108 includes a module-lens surface 118 and a second spacer structure formed between the device-wafer surface 112 and the module-lens surface 118. In some implementations, each of the module-lens structure 108 includes a curved lens or a metalens. In some implementations, a thickness of the second spacer structure corresponds to a focal length associated with the module-lens surface 118. For example, the thickness of the second spacer structure can range from 100 μm to 3000 μm. The second spacer structure may be formed using a polymer material, silicon, or a dielectric material. In some implementations, the module-lens structure 108 further includes a band pass filter 110 formed over the module-lens surface 118 or between the second spacer structure and the module-lens surface 118.

The optical sensor package 100 further includes electrical contacts 122 formed over the circuit-wafer surface 114 to establish electrical connections to the plurality of optical sensing pixels and the application-specific-integrated-circuit. In some implementations, the electrical contacts 122 include through-silicon-vias (TSV) formed in the circuit wafer 104, and electrical bond pads formed over the through-silicon-vias.

In some implementations, one or more properties associated with the microlens array 106 or the module-lens structure 108 is tunable by a voltage bias. For example, the one or more properties include a pass-band wavelength, a transmission percentage, and/or a focusing length associated with the microlens array 106 or the module-lens structure 108.

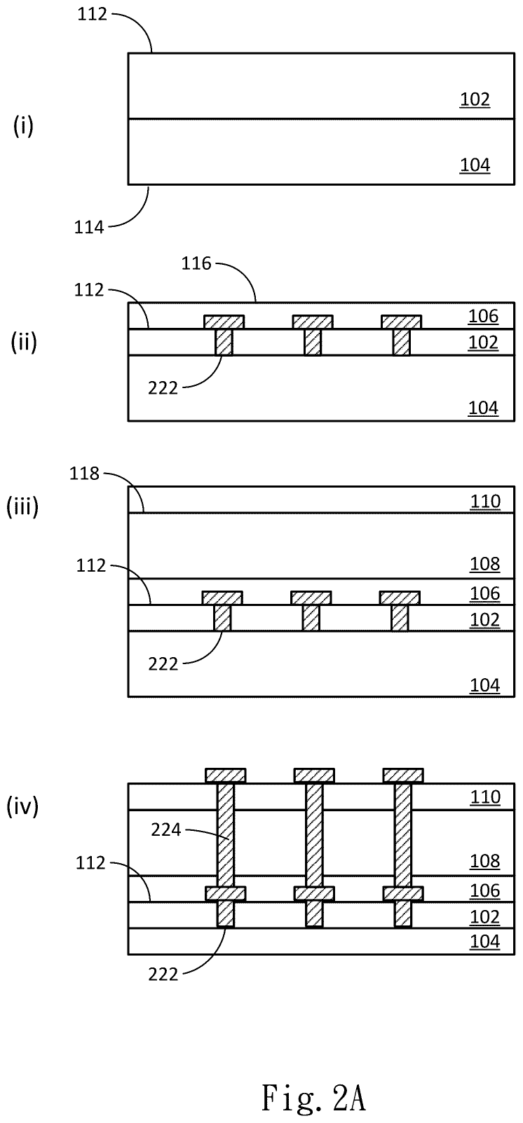

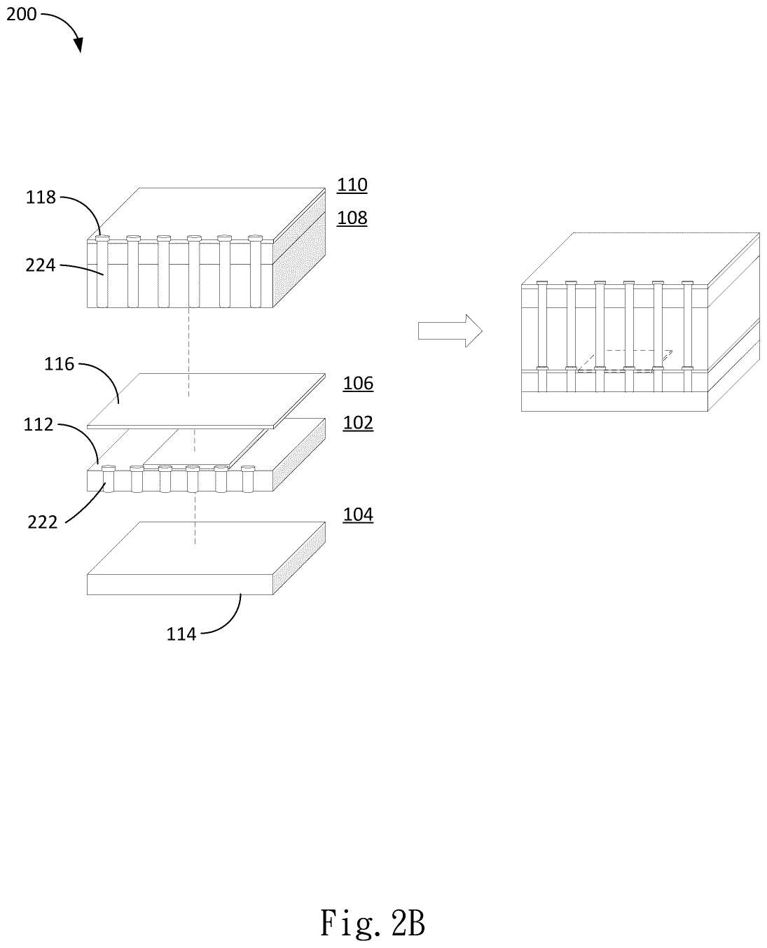

FIG. 2A illustrates an example process for manufacturing an optical sensor package. Step (i) in FIG. 2A is similar to that described in reference to step (i) in FIG. 1A, where the device wafer 102 and the circuit wafer 104 are bonded.

Referring to step (ii) in FIG. 2A, the process further includes forming a plurality of microlens arrays 106 over the device-wafer surface 112, where each microlens of the microlens arrays 106 corresponds to a particular optical sensing pixel. The plurality of microlens arrays 106 can include polymer materials. In some implementations, the plurality of microlens arrays 106 include a first spacer structure and a microlens surface 116, where the first spacer structure is formed between the device-wafer surface 112 and the microlens surface 116. In some implementations, forming the plurality of microlens arrays 106 over the device-wafer surface 112 may include polishing the device wafer 102 to a predetermined thickness before forming the plurality of microlens arrays 106.

Referring to step (ii) in FIG. 2A, the process further includes forming electrical contacts 222 (e.g., through silicon vias and/or bond pads) in the device wafer 102 to establish electrical connections between optical sensing pixels of the device wafer 102 and circuitry of the circuit wafer 104. In some implementations, the electrical contacts 222 are formed before forming the plurality of microlens arrays 106. In some other implementations, the electrical contacts 222 are formed after forming the plurality of microlens arrays 106.

Referring to step (iii) in FIG. 2A, similar to that described in reference to step (iii) in FIG. 1A, the process further includes forming a plurality of module-lens structures 108 over the plurality of microlens arrays 106, where each module-lens structure 108 corresponds to a particular microlens array of the plurality of microlens arrays 106. In some implementations, forming the plurality of module-lens structures 108 further includes forming a band pass filter 110 over the module-lens surface 118 or between the second spacer structure and the module-lens surface 118. In some implementations, a module-lens structure 108 may include one or more additional spacer structures arranged under and/or over the module-lens surface 118. In some implementations, a module-lens structure 108 may include one or more additional module-lens surfaces separated by one or more additional spacer structures in order to further manipulate optical signals.

Referring to step (iv) in FIG. 2A, the process further includes forming electrical contacts 224 over the device-wafer surface 112 to establish electrical connections to the plurality of optical sensing pixels and the application-specific-integrated-circuit. In some implementations, forming the electrical contacts 224 over the device-wafer surface 112 includes forming through-silicon-vias (TSV) on the device wafer 102, and forming electrical bond pads over the through-silicon-vias. In some implementations, forming the electrical contacts 224 over the device-wafer surface 112 further includes polishing the device wafer 102 to a predetermined thickness prior to forming the TSV. In some implementations, forming the electrical contacts 224 over the device-wafer surface 112 further includes establishing electrical contacts between the electrical contacts 222 and the electrical contacts 224.

In some implementations, the process further includes thinning the circuit wafer 104 during the process (e.g., prior to forming the plurality of module-lens structures 108 over the plurality of microlens arrays 106, or after forming the electrical contacts 224, etc.). In some implementations, the process further includes dicing the bonded wafer after forming the electrical contacts 224. In some implementations, the process further includes forming wire bonds between the electrical contacts 224 and a package substrate, where the package substrate may be a printed circuit board or a silicon substrate. Referring to FIG. 6 as an example, the bonded chip 608 is bonded to the PCB 610 via wire bonds.

FIG. 2B illustrates an optical sensor package 200 manufactured by the process as described in reference to FIG. 2A. Similar to the optical sensor package 100 described in reference to FIG. 1B, the optical sensor package 200 includes a bonded substrate having a device-wafer surface 112 and a circuit-wafer surface 114, and a microlens array 106 formed over the device-wafer surface 112, where each microlens of the microlens arrays 106 corresponds to a particular optical sensing pixel. The optical sensor package 200 further includes a module-lens structure 108 formed over the microlens surface 116, and a band pass filter 110 formed over the module-lens surface 118 or between the second spacer structure and the module-lens surface 118.

The optical sensor package 200 further includes electrical contacts 222 formed in the device wafer 102 to establish electrical connections to the plurality of optical sensing pixels and the application-specific-integrated-circuit. The optical sensor package 200 further includes electrical contacts 224 formed over the device-wafer surface 112 to establish electrical connections to the plurality of optical sensing pixels and the application-specific-integrated-circuit. In some implementations, the electrical contacts 222 and/or 224 includes through-silicon-vias (TSV), and electrical bond pads formed over the through-silicon-vias.

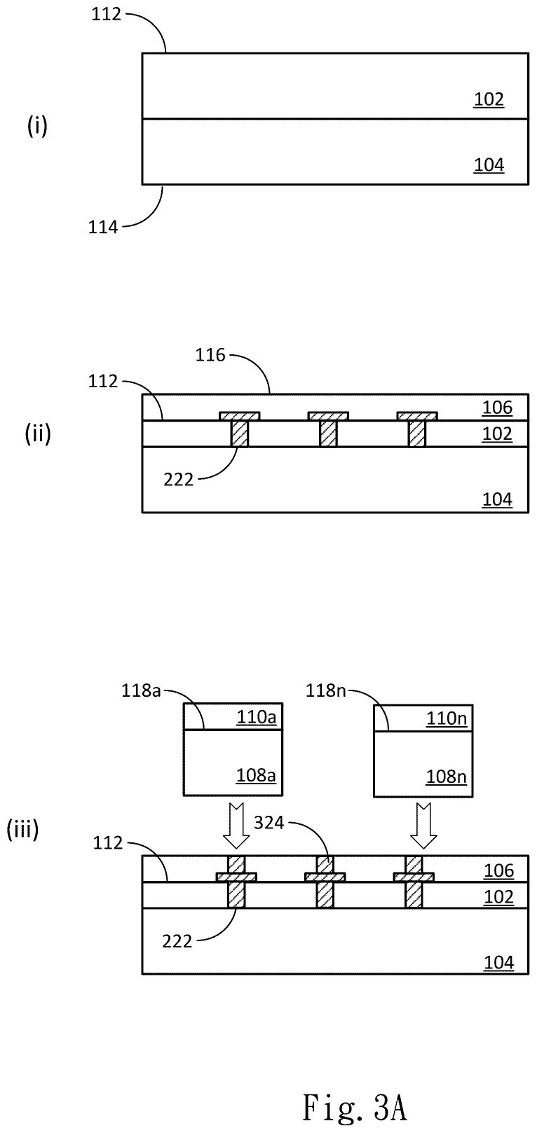

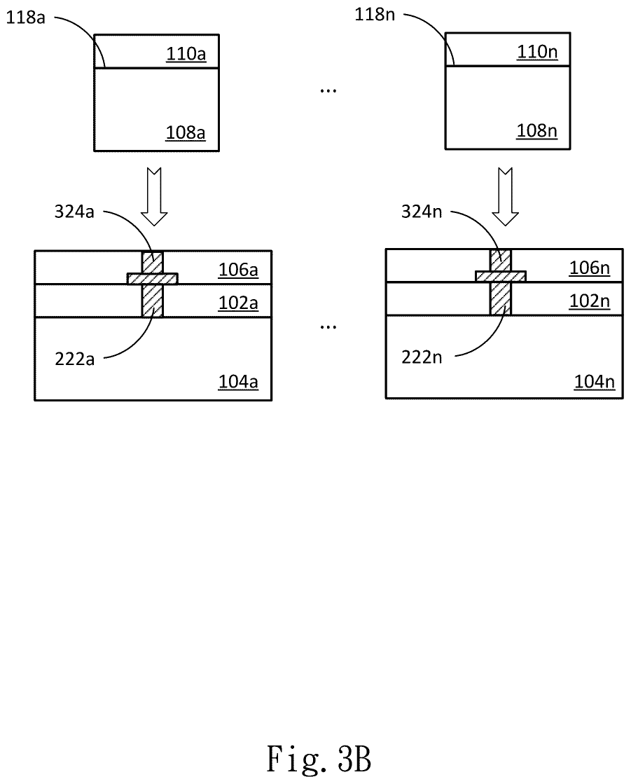

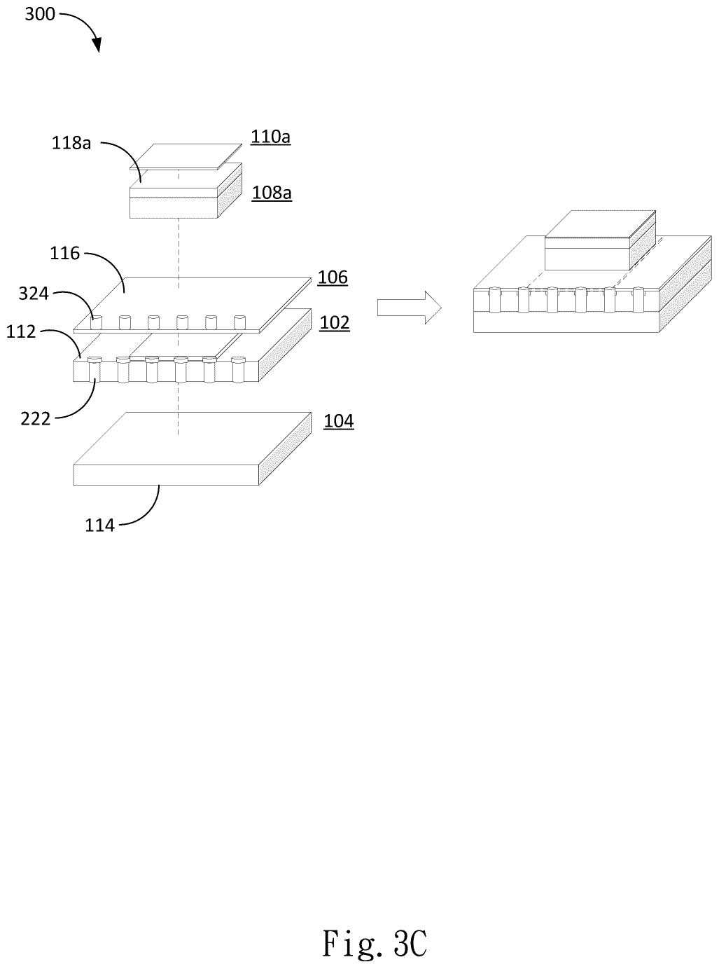

FIG. 3A illustrates an example process for manufacturing an optical sensor package. Step (i) in FIG. 3A is similar to that described in reference to step (i) in FIG. 1A/FIG. 2A, where the device wafer 102 and the circuit wafer 104 are bonded. Similar to step (ii) described in FIG. 2A, referring to step (ii) in FIG. 3A, the process further includes forming a plurality of microlens arrays 106 over the device-wafer surface 112, where each microlens of the microlens arrays 106 corresponds to a particular optical sensing pixel. The process further includes forming electrical contacts 222 (e.g., through silicon vias and/or bond pads) in the device wafer 102 to establish electrical connections between optical sensing pixels of the device wafer 102 and circuitry of the circuit wafer 104.

Referring to step (iii) in FIG. 3A, the process further includes bonding a plurality of diced module-lens structures 108a-108n over the plurality of microlens arrays 106, where each diced module-lens structure 108a-108n corresponds to a respective microlens array 106, and where n is a positive integer. Each of the plurality of diced module-lens structures 108a-108n may include a module-lens surface 118a-118n and a second spacer structure formed between the device-wafer surface 112 and the module-lens surface 118a-118n. In some implementations, the process further includes forming a band pass filter 110a-110n over the module-lens surface 118a-118n or between the second spacer structure and the module-lens surface 118a-118n. The band pass filter 110a-110n may be formed on a wafer prior to dicing the diced module-lens structures 108a-108n. In some implementations, a module-lens structure 108 may include one or more additional spacer structures arranged under and/or over the module-lens surface 118a-118n. In some implementations, a module-lens structure 108 may include one or more additional module-lens surfaces separated by one or more additional spacer structures in order to further manipulate optical signals.

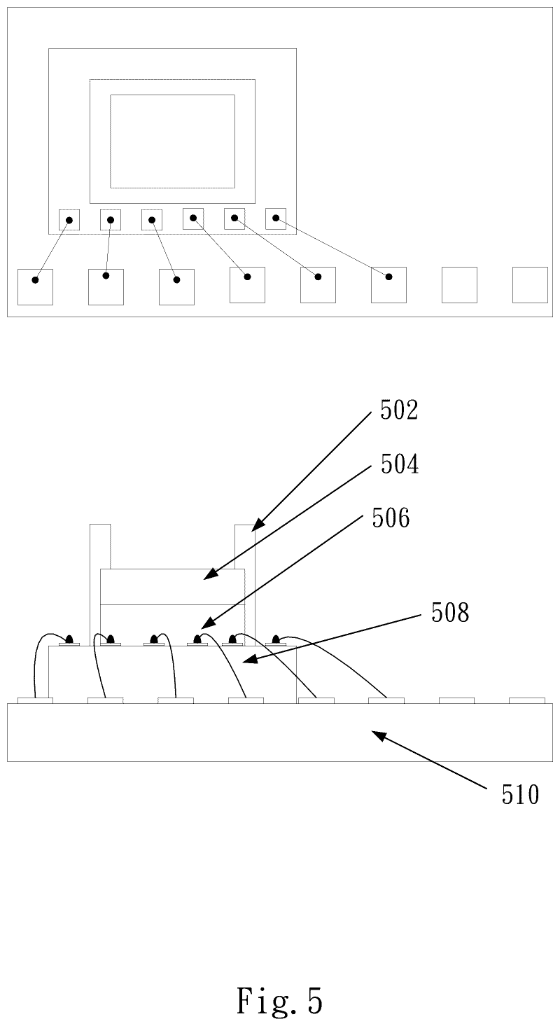

Referring to FIG. 5 as an example, bonding a module-lens structure (e.g., 108a) over a microlens array 106 may include placing a module lens 504 in a housing 502, and bonding (e.g., using an epoxy) the housing 502 to the bonded chip 508 (e.g., the bonded substrate having a device-wafer surface 112 and a circuit-wafer surface 114). In some implementations, an airgap 506 (e.g., a second spacer structure formed between the device-wafer surface 112 and the module-lens surface 118a-118n) is formed between the module lens 504 and the bonded chip 508. In some other implementations, the airgap 506 may be partially or completely filled with one or more layers of spacer materials (e.g., polymer, glass, etc.). Referring to FIG. 6 as another example, bonding a module-lens structure 108 over a microlens array 106 may alternatively include bonding a module lens 604 to the bonded chip 608 using one or more layers of spacer materials 606 (e.g., polymer, glass, etc.).

In some implementations, the process may include dicing the bonded wafer prior to bonding a module-lens structure 108 over a microlens array 106. Referring to FIG. 3B as an example, the bonded wafer with the microlens array 106 may be diced into n bonded dies, and the diced module-lens structures 108a-108n may then be bonded to each of the n bonded dies.

Referring back to step (iii) in FIG. 3A, in some implementations, the process may further include forming electrical contacts 324 over the device-wafer surface 112 (e.g., through silicon vias and/or bond pads) to establish electrical connections to the plurality of optical sensing pixels and the application-specific-integrated-circuit. The electrical contacts 324 may be formed prior to or after bonding the plurality of diced module-lens structures 108a-108n over the plurality of microlens arrays 106. In some implementations, if the diced module-lens structures 108a-108n are bonded over the electrical contacts 222, the electrical contacts 324 may be formed through the layers that include the microlens arrays 106, the diced module-lens structures 108a-108n, and the band pass filter 110a-110n. In some other implementations, if the diced module-lens structures 108a-108n are not bonded over the electrical contacts 222, the electrical contacts 324 may be formed through the layer that include the microlens arrays 106.

In some implementations, the process further includes thinning the circuit wafer 104 during the process (e.g., prior to forming the plurality of module-lens structures 108 over the plurality of microlens arrays 106, or after forming the electrical contacts 324, etc.). In some implementations, the process further includes dicing the processed wafer after forming the electrical contacts 324. In some implementations, the process further includes forming wire bonds between the electrical contacts 324 and a package substrate, where the package substrate may be a printed circuit board or a silicon substrate. Referring to FIG. 5 as an example, the bonded chip 508 is bonded to the transmitter chip 510 via wire bonds. Referring to FIG. 6 as another example, the bonded chip 608 is bonded to the PCB 610 via wire bonds.

FIG. 3C illustrates an optical sensor package 300 manufactured by the process as described in reference to FIG. 3A and/or FIG. 3B. Similar to the optical sensor package 200 described in reference to FIG. 2B, the optical sensor package 300 includes a bonded substrate having a device-wafer surface 112 and a circuit-wafer surface 114, and a microlens array 106 formed over the device-wafer surface 112, where each microlens of the microlens arrays 106 corresponds to a particular optical sensing pixel. The optical sensor package 300 further includes a module-lens structure 108a formed over the microlens array 106, and a band pass filter 110a formed over the module-lens surface 118a or between the second spacer structure and the module-lens surface 118a.

The optical sensor package 300 further includes electrical contacts 222 formed in the device wafer 102 to establish electrical connections to the plurality of optical sensing pixels and the application-specific-integrated-circuit. The optical sensor package 300 further includes electrical contacts 324 formed over the device-wafer surface 112 to establish electrical connections to the plurality of optical sensing pixels and the application-specific-integrated-circuit. In some implementations, the electrical contacts 222 and/or 324 includes through-silicon-vias (TSV), and electrical bond pads formed over the through-silicon-vias.

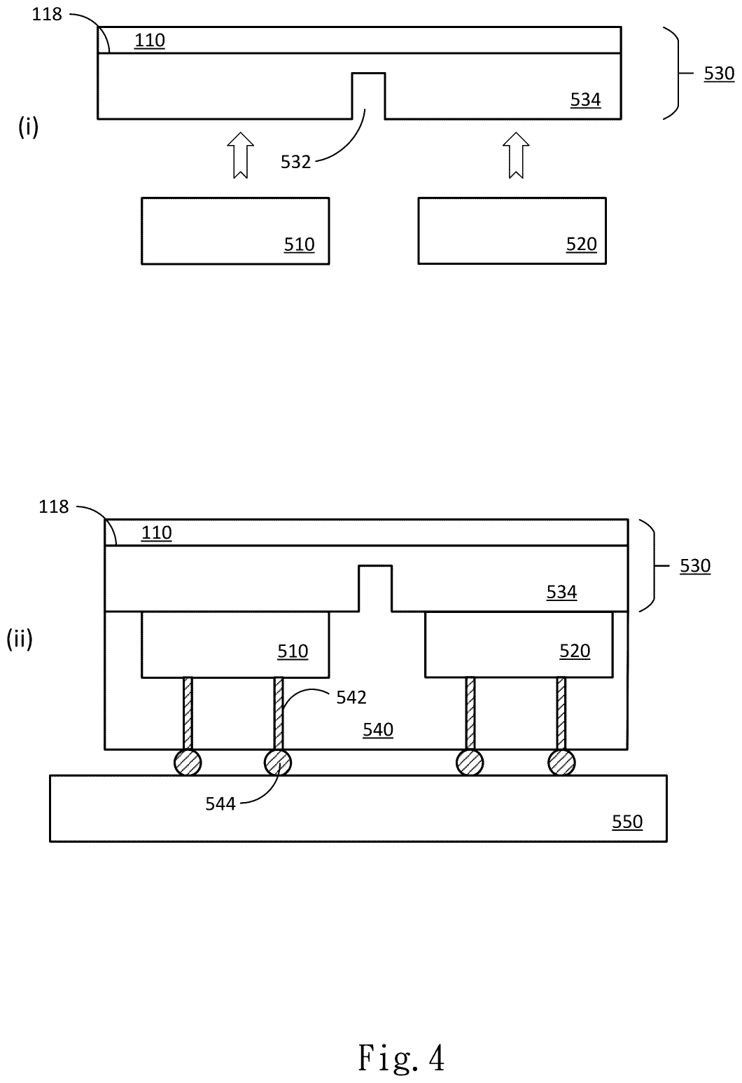

FIG. 4 illustrates an example process for manufacturing an optical sensor package that integrates a transmitter chip 510 and a receiver chip 520. Referring to step (i), the process includes bonding (e.g., using an epoxy) a transmitter chip 510 and a receiver chip 520 to a module lens structure 530 having a spacer structure 534, a module-lens surface 118, and optionally a band-pass filter 110. The transmitter chip 510 may include a light source (e.g., a light emitting diode, a laser, etc.). The receiver chip 520 may include any implementation of a diced bonded-die described in this disclosure. The module lens structure 530 has a larger area than the transmitter chip 510 and the receiver chip 520. In some implementations, the process may include forming a trench 532 in the module lens structure 530 that is used to reduce or block undesirable optical leakage from the transmitter chip 510 to the receiver chip 520.

Referring to step (ii) of FIG. 4, the process includes forming a planarization layer 540 (e.g., polymer, oxide, or any other suitable insulating material), forming electrical contacts 542 and 544 to establish electrical connections to the transmitter chip 510 and the receiver chip 520, and bonding planarization layer 540 to a package substrate 550, where the package substrate 550 may be a printed circuit board or a silicon substrate.

Various means can be configured to perform the methods, operations, and processes described herein. For example, any of the systems and apparatuses (e.g., optical sensing apparatus and related circuitry) can include unit(s) and/or other means for performing their operations and functions described herein. In some implementations, one or more of the units may be implemented separately. In some implementations, one or more units may be a part of or included in one or more other units. These means can include processor(s), microprocessor(s), graphics processing unit(s), logic circuit(s), dedicated circuit(s), application-specific integrated circuit(s), programmable array logic, field-programmable gate array(s), controller(s), microcontroller(s), and/or other suitable hardware. The means can also, or alternately, include software control means implemented with a processor or logic circuitry, for example. The means can include or otherwise be able to access memory such as, for example, one or more non-transitory computer-readable storage media, such as random-access memory, read-only memory, electrically erasable programmable read-only memory, erasable programmable read-only memory, flash/other memory device(s), data register(s), database(s), and/or other suitable hardware.

As used herein, the terms such as “first”, “second”, “third”, “fourth” and “fifth” describe various elements, components, regions, layers and/or sections, these elements, components, regions, layers and/or sections should not be limited by these terms. These terms may be only used to distinguish one element, component, region, layer or section from another. The terms such as “first”, “second”, “third”, “fourth” and “fifth” when used herein do not imply a sequence or order unless clearly indicated by the context. The terms “photo-detecting”, “photo-sensing”, “light-detecting”, “light-sensing” and any other similar terms can be used interchangeably.

Aspects of the disclosure have been described in terms of illustrative embodiments thereof. Numerous other embodiments, modifications, and/or variations within the scope and spirit of the appended claims can occur to persons of ordinary skill in the art from a review of this disclosure. Any and all features in the following claims can be combined and/or rearranged in any way possible. Accordingly, the scope of the present disclosure is by way of example rather than by way of limitation, and the subject disclosure does not preclude inclusion of such modifications, variations or additions to the present subject matter as would be readily apparent to one of ordinary skill in the art. Moreover, terms are described herein using lists of example elements joined by conjunctions such as “and,” “or,” “but,” etc. It should be understood that such conjunctions are provided for explanatory purposes only. Lists joined by a particular conjunction such as “or,” for example, can refer to “at least one of” or “any combination of” example elements listed therein. Also, terms such as “based on” should be understood as “based at least in part on”.

Those of ordinary skill in the art, using the disclosures provided herein, will understand that the elements of any of the claims discussed herein can be adapted, rearranged, expanded, omitted, combined, or modified in various ways without deviating from the scope of the present disclosure. Some of the claims are described with a letter reference to a claim element for exemplary illustrated purposes and is not meant to be limiting. The letter references do not imply a particular order of operations. For instance, letter identifiers such as (a), (b), (c), . . . , (i), (ii), (iii), . . . , etc. may be used to illustrate method operations. Such identifiers are provided for the case of the reader and do not denote a particular order of steps or operations. An operation illustrated by a list identifier of (a), (i), etc. can be performed before, after, and/or in parallel with another operation illustrated by a list identifier of (b), (ii), etc.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing one or more optical sensor packages, comprising:
forming a bonded wafer by bonding (i) a device wafer comprising a plurality of optical sensing pixels and (ii) a circuit wafer comprising application-specific-integrated-circuit configured to operate the optical sensing pixels, wherein the bonded wafer includes a device-wafer surface and a circuit-wafer surface;
forming a plurality of microlens arrays over the device-wafer surface, wherein each microlens of the microlens arrays corresponds to a particular optical sensing pixel;
forming a plurality of module-lens structures over the plurality of microlens arrays, wherein each module-lens structure corresponds to a particular microlens array of the plurality of microlens arrays; and
forming electrical contacts to establish electrical connections to the plurality of optical sensing pixels and the application-specific-integrated-circuit.

2. The method of claim 1, wherein forming the plurality of microlens arrays over the device-wafer surface further comprises polishing the device-wafer surface to a predetermined thickness before forming the plurality of microlens arrays.

3. The method of claim 1, wherein the plurality of microlens arrays include a first spacer structure and a microlens surface, wherein the first spacer structure is formed between the device-wafer surface and the microlens surface.

4. The method of claim 1, wherein the plurality of microlens arrays comprise polymer materials or one or more layers of metalens.

5. The method of claim 1, wherein the plurality of module-lens structures include a module-lens surface and a second spacer structure formed between the device-wafer surface and the module-lens surface, and wherein a thickness of the second spacer structure corresponds to a focal length associated with the module-lens surface.

6. The method of claim 5, wherein forming the plurality of module-lens structures further comprises forming a band pass filter (i) over the module-lens surface or (ii) between the second spacer structure and the module-lens surface.

7. The method of claim 5, wherein the thickness of the second spacer structure ranges from 100 μm to 3000 μm.

8. The method of claim 5, wherein each of the plurality of module-lens structures comprise a curved lens or a metalens.

9. The method of claim 5, wherein the second spacer structure comprises a polymer material, a dielectric material, or silicon.

10. The method of claim 1, wherein forming the plurality of module-lens structures over the plurality of microlens arrays further comprises arranging a module lens structure of the plurality of module-lens structures in a housing, and bonding the housing to the bonded wafer.

11. The method of claim 1, wherein forming the plurality of module-lens structures over the plurality of microlens arrays further comprises bonding a module lens structure of the plurality of module-lens structures to the bonded wafer using one or more layers of spacer materials including one or more of polymer or oxide.

12. The method of claim 1, wherein forming the electrical contacts further comprises forming the electrical contacts over the circuit-wafer surface.

13. The method of claim 1, wherein forming the electrical contacts further comprises forming the electrical contacts over the device-wafer surface.

14. The method of claim 1, wherein forming the electrical contacts further comprises:
forming through-silicon-vias (TSV) in the circuit wafer or the device wafer; and
forming electrical bond pads over the through-silicon-vias.

15. The method of claim 1, wherein forming the electrical contacts further comprises polishing the circuit wafer to a predetermined thickness prior to forming the electrical contacts.

16. The method of claim 1, further comprises dicing the bonded wafer after forming the electrical contacts.

17. The method of claim 1, further comprises dicing the bonded wafer prior to forming the plurality of module-lens structures.

18. The method of claim 1, further comprising forming wire bonds between the electrical contacts and a package substrate.

19. The method of claim 18, wherein the package substrate comprises a printed circuit board or a silicon substrate.

20. The method of claim 1, wherein the device wafer and the circuit wafer comprise silicon, and wherein the plurality of optical sensing pixels comprise germanium.
